(19) United States
(12) Patent Application Publication
(10) Pub. No.: US 2024/0379639 A1
(43) Pub. Date: Nov. 14, 2024

(54) SEMICONDUCTOR PACKAGE

(71) Applicant: SAMSUNG ELECTRONICS CO., LTD., Suwon-si (KR)

(72) Inventors: Myung Joo Park, Suwon-si (KR); Hyung Jun Jeon, Suwon-si (KR); Pil-Kyu Kang, Suwon-si (KR)

(21) Appl. No.: 18/397,837

(22) Filed: Dec. 27, 2023

(30) Foreign Application Priority Data
May 11, 2023 (KR) 10-2023-0061093

(51) Int. Cl. H01L 25/16; H01L 23/498; H10B 80/00

(52) U.S. Cl. CPC H01L 25/16; H01L 23/49833; H10B 80/00; H01L 23/3128; H01L 24/05; H01L 24/13; H01L 24/16; H01L 2224/05609; H01L 2224/05611; H01L 2224/05617; H01L 2224/05618; H01L 2224/05623; H01L 2224/05624; H01L 2224/05639; H01L 2224/05647; H01L 2224/05649; H01L 2224/05657; H01L 2224/05666; H01L 2224/05669; H01L 2224/0567; H01L 2224/05671; H01L 2224/05681; H01L 2224/05693; H01L 2224/13109; H01L 2224/13111; H01L 2224/13113; H01L 2224/13116; H01L 2224/13118; H01L 2224/1312; H01L 2224/13139; H01L 2224/13144; H01L 2224/13147; H01L 2224/13155; H01L 2224/16227; H01L 2924/01006; H01L 2924/01032; H01L 2924/01038

(57) ABSTRACT

An example semiconductor package includes a structure, a first semiconductor chip disposed on an upper surface of the structure and electrically connected to the structure, a dummy semiconductor chip disposed on and contacting the upper surface of the structure, a molding layer surrounding a sidewall of the first semiconductor chip and a sidewall of the dummy semiconductor chip on the upper surface of the structure, a redistribution layer disposed on an upper surface of the first semiconductor chip, an upper surface of the dummy semiconductor chip, and an upper surface of the molding layer, a first through-via extending through the molding layer in a vertical direction and electrically connecting the structure and the redistribution layer, a second through-via extending through the dummy semiconductor chip in the vertical direction and electrically connecting the structure and the redistribution layer, and a capacitor disposed inside the dummy semiconductor chip.

### CROSS-REFERENCE TO RELATED APPLICATION

This application claims priority to Korean Patent Application No. 10-2023-0061093, filed on May 11, 2023, in the Korean Intellectual Property Office, and all the benefits accruing therefrom under 35 U.S.C. 119, the disclosure of which in its entirety is herein incorporated by reference.

### BACKGROUND

Recently, a high-performance semiconductor package is required. The high-performance semiconductor package may include structures such as a substrate, a plurality of semiconductor chips, and a redistribution layer integrated with each other. For example, in the semiconductor package, a lower structure and an upper structure may be electrically connected to each other using a via extending through a mold layer. In this case, a region where the via is disposed is filled with the mold layer. Thus, the region where the via is disposed is vulnerable to warpage and thus the via is deteriorated in a process of manufacturing the semiconductor package. In order to solve this problem, research is being conducted to structurally reinforce the region where the via is disposed.

### SUMMARY

The present disclosure relates to semiconductor packages. In an example semiconductor package, a dummy semiconductor chip including silicon is disposed in a molding layer, and a through-via is disposed in the dummy semiconductor chip, thereby preventing warpage of the through-via from occurring, and thus preventing the through-via from deteriorating. In another example semiconductor package, a dummy semiconductor chip including silicon is disposed in a molding layer, and a capacitor is disposed in the dummy semiconductor chip, thereby improving electrical reliability of the capacitor.

In some implementations, a semiconductor device comprises a structure, a first semiconductor chip disposed on an upper surface of the structure, and the first semiconductor chip directly electrically connected to the structure, a dummy semiconductor chip disposed on the upper surface of the structure, the dummy semiconductor chip being in contact with the upper surface of the structure, the dummy semiconductor chip spaced apart from the first semiconductor chip in a horizontal direction, the dummy semiconductor chip including silicon, a molding layer surrounding each of a sidewall of the first semiconductor chip and a sidewall of the dummy semiconductor chip on the upper surface of the structure, a redistribution layer disposed on an upper surface of the first semiconductor chip, an upper surface of the dummy semiconductor chip and an upper surface of the molding layer, a first through-via extending through the molding layer in a vertical direction, the first through-via electrically connecting the structure and the redistribution layer to each other, a second through-via extending through the dummy semiconductor chip in the vertical direction, the second through-via electrically connecting the structure and the redistribution layer to each other, and a capacitor disposed inside the dummy semiconductor chip, the capacitor electrically connected to the redistribution layer.

In some implementations, a semiconductor device comprises a structure, a semiconductor chip disposed on an upper surface of the structure, the semiconductor chip directly electrically connected to the structure, a dummy semiconductor chip disposed on the upper surface of the structure, the dummy semiconductor chip being in contact with the upper surface of the structure, the dummy semiconductor chip spaced apart from the semiconductor chip in a horizontal direction, the dummy semiconductor chip including a first insulating layer disposed on the upper surface of the structure, a base material layer disposed on the first insulating layer and including silicon, and a second insulating layer disposed on the base material layer, a molding layer surrounding each of a sidewall of the semiconductor chip and a sidewall of the dummy semiconductor chip on the upper surface of the structure, a first through-via extending through the molding layer in a vertical direction, the first through-via electrically connected to the structure, a second through-via extending through each of the first insulating layer, the base material layer and the second insulating layer in the vertical direction, the second through-via electrically connected to the structure, and a capacitor disposed inside the base material layer, wherein an upper surface of the molding layer, an upper surface of the second through-via and an upper surface of the dummy semiconductor chip are coplanar with each other.

In some implementations, a semiconductor device comprises a structure, a semiconductor chip disposed on an upper surface of the structure, the semiconductor chip directly electrically connected to the structure, a dummy semiconductor chip disposed on the upper surface of the structure, the dummy semiconductor chip being in contact with the upper surface of the structure, the dummy semiconductor chip spaced apart from the semiconductor chip in a horizontal direction, the dummy semiconductor chip including a first insulating layer disposed on the upper surface of the structure, a base material layer disposed on the first insulating layer and including silicon, and a second insulating layer disposed on the base material layer, a molding layer surrounding each of a sidewall of the semiconductor chip and a sidewall of the dummy semiconductor chip on the upper surface of the structure, a redistribution layer disposed on an upper surface of the semiconductor chip, an upper surface of the dummy semiconductor chip and an upper surface of the molding layer, a first through-via extending through the molding layer in a vertical direction, the first through-via electrically connecting the structure and the redistribution layer to each other, a second through-via extending through each of the first insulating layer, the base material layer, and the second insulating layer in the vertical direction, the second through-via electrically connecting the structure and the redistribution layer to each other, and a capacitor disposed inside the base material layer, the capacitor electrically connected to the redistribution layer, wherein a lower surface of the second through-via is coplanar with a lower surface of the dummy semiconductor chip, wherein the upper surface of the molding layer, the upper surface of the second through-via and the upper surface of the dummy semiconductor chip are coplanar with each other, and wherein the upper surface of the semiconductor chip is in contact with the redistribution layer, the semiconductor chip is directly electrically connected to the redistribution layer.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims or combinations thereof.

### BRIEF DESCRIPTION OF THE DRAWINGS

The above and other aspects and features of the present disclosure will become more apparent by describing in detail illustrative implementations thereof with reference to the attached drawings.

FIG. 1 is a diagram for illustrating an example of a semiconductor package.

FIG. 2 is a diagram for illustrating an example of a dummy semiconductor chip as shown in FIG. 1.

FIG. 3 to FIG. 7 are diagrams of intermediate structures corresponding to intermediate steps to illustrate an example of a method for manufacturing the semiconductor package as shown in FIG. 1.

FIG. 8 is a diagram for illustrating an example of a semiconductor package.

FIG. 9 is a diagram for illustrating another example of a semiconductor package.

FIG. 10 to FIG. 14 are diagrams of intermediate structures corresponding to intermediate steps to illustrate an example of a method for manufacturing the semiconductor package as shown in FIG. 9.

FIG. 15 is a diagram for illustrating another example of a semiconductor package.

FIG. 16 is a diagram for illustrating another example of a semiconductor package.

FIG. 17 to FIG. 24 are diagrams of intermediate structures corresponding to intermediate steps for illustrating an example of a method for manufacturing the semiconductor package as shown in FIG. 16.

FIG. 25 is a diagram for illustrating another example of a semiconductor package.

### DETAILED DESCRIPTIONS

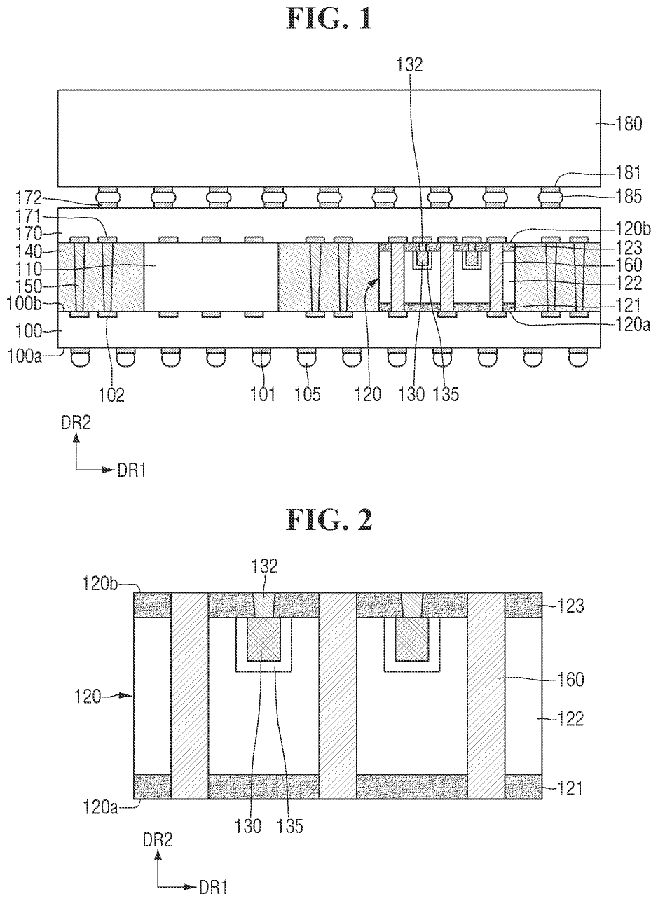

Hereinafter, a semiconductor package according to some implementations of the present disclosure are described with reference to FIGS. 1 and 2.

FIG. 1 is a diagram for illustrating an example of a semiconductor package. FIG. 2 is a diagram for illustrating an example of a dummy semiconductor chip as shown in FIG. 1.

Referring to FIG. 1 and FIG. 2, the semiconductor package includes a structure 100, a first conductive pad 101, a second conductive pad 102, a first connection terminal 105, a first semiconductor chip 110, a dummy semiconductor chip 120, a capacitor 130, a capacitor via 132, a capacitor insulating layer 135, a first molding layer 140, a first through-via 150, a second through-via 160, a redistribution layer 170, a third conductive pad 171, a fourth conductive pad 172, a second semiconductor chip 180, a fifth conductive pad 181, and a third connection terminal 185.

The structure 100 includes a lower surface 100a and an upper surface 100b opposite to the lower surface 100a. The structure 100 may be, for example, a printed circuit board (PCB) or a ceramic substrate. However, the present disclosure is not limited thereto. In some implementations, the structure 100 is a redistribution layer including a plurality of wirings therein.

When the structure 100 is embodied as the printed circuit board, the structure 100 may be made of at least one material selected from phenol resin, epoxy resin, and polyimide. For example, the structure 100 may include at least one material selected from FR4, tetrafunctional epoxy, polyphenylene ether, epoxy/polyphenylene oxide, BT (bismaleimide triazine), thermount, cyanate ester, polyimide, and liquid crystal polymer.

Hereinafter, a horizontal direction DR1 may be defined as a direction parallel to the upper surface 100b of the structure 100. A vertical direction DR2 may be defined as a direction perpendicular to the horizontal direction DR1. That is, the vertical direction DR2 may be defined as a direction perpendicular to the upper surface 100b of the structure 100. For example, the first conductive pad 101 may be disposed on the structure 100. The second conductive pad 102 may be disposed in the structure 100.

The first conductive pad 101 is disposed on the lower surface 100a of the structure 100. A plurality of first conductive pads 101 may be disposed on the lower surface 100a of the structure 100. Although the first conductive pad 101 is illustrated as protruding from the lower surface 100a of the structure 100 in FIG. 1, the present disclosure is not limited thereto. The second conductive pad 102 is disposed beneath the upper surface 100b of the structure 100. A plurality of second conductive pads 102 may be disposed beneath the upper surface 100b of the structure 100. At least a portion of the second conductive pad 102 may be not covered with the upper surface 100b of the structure 100 so as to exposed.

Each of the first conductive pad 101 and the second conductive pad 102 may include a conductive material. Each of the first conductive pad 101 and the second conductive pad 102 may include, for example, at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), or zirconium (Zr). However, the present disclosure is not limited thereto.

The first connection terminal 105 is disposed on the lower surface 100a of the structure 100. The first connection terminal 105 is connected to the first conductive pad 101. The structure 100 is electrically connected to an external device via the first connection terminal 105. The first connection terminal 105 includes, for example, at least one of tin (Sn), indium (In), lead (Pb), zinc (Zn), nickel (Ni), gold (Au), silver (Ag), copper (Cu), antimony (Sb), bismuth (Bi), or combinations thereof. However, the present disclosure is not limited thereto.

The first semiconductor chip 110 is disposed on the upper surface 100b of the structure 100. For example, the first semiconductor chip 110 may contact the upper surface 100b of the structure 100. The first semiconductor chip 110 may be connected to the second conductive pad 102. The first semiconductor chip 110 may be directly electrically connected to the structure 100 via the second conductive pad 102.

For example, the first semiconductor chip 110 may be a logic semiconductor chip. For example, the first semiconductor chip 110 may be an application processor (AP) such as CPU (Central Processing Unit), GPU (Graphic Processing Unit), FPGA (Field-Programmable Gate Array), a digital signal processor, a cryptographic processor, a microprocessor, a microcontroller, or ASIC (Application-Specific IC).

For example, the first semiconductor chip 110 may be a memory semiconductor chip. For example, the first semiconductor chip 110 may be a volatile memory such as DRAM (dynamic random access memory) or SRAM (static random access memory), or may be a non-volatile memory such as a flash memory, PRAM (Phase-change Random Access Memory), MRAM (Magnetoresistive Random Access Memory), FeRAM (Ferroelectric Random Access Memory) or RRAM (Resistive Random Access Memory).

The dummy semiconductor chip 120 is disposed on the upper surface 100b of the structure 100. For example, the dummy semiconductor chip 120 may contact the upper surface 100b of the structure 100. For example, the dummy semiconductor chip 120 may be spaced apart from the structure 100 in the horizontal direction DR1. For example, the dummy semiconductor chip 120 may include a first insulating layer 121, a base material layer 122, and a second insulating layer 123.

For example, the first insulating layer 121 may constitute a lower portion of the dummy semiconductor chip 120. That is, a lower surface of the first insulating layer 121 may be defined as a lower surface 120a of the dummy semiconductor chip 120. The first insulating layer 121 may include an insulating material. The base material layer 122 may be disposed on an upper surface of the first insulating layer 121. For example, the base material layer 122 may include silicon (Si). The second insulating layer 123 may be disposed on an upper surface of the base material layer 122. The second insulating layer 123 may constitute an upper portion of the dummy semiconductor chip 120. That is, an upper surface of the second insulating layer 123 may be defined as an upper surface 120b of the dummy semiconductor chip 120. The second insulating layer 123 may include an insulating material.

The first molding layer 140 is disposed on the upper surface 100b of the structure 100. The first molding layer 140 may surround each of a sidewall of the first semiconductor chip 110 and a sidewall of the dummy semiconductor chip 120. For example, an upper surface of the first molding layer 140 may be coplanar with each of an upper surface of the first semiconductor chip 110 and the upper surface 120b of the dummy semiconductor chip 120. For example, the first molding layer 140 may include, as a base material, PIE (Photo Imagable Encapsulant), epoxy molding compound (EMC), or two or more types of silicon hybrid materials in a form of a film.

The redistribution layer 170 is disposed on each of the upper surface of the first semiconductor chip 110, the upper surface 120b of the dummy semiconductor chip 120, and the upper surface of the first molding layer 140. For example, a lower surface of the redistribution layer 170 may contact each of the upper surface of the first semiconductor chip 110, the upper surface 120b of the dummy semiconductor chip 120, and the upper surface of the first molding layer 140. A plurality of wirings may be disposed in the redistribution layer 170. For example, the third conductive pad 171 and the fourth conductive pad 172 may be disposed in the redistribution layer 170.

The third conductive pad 171 is disposed on the lower surface of the redistribution layer 170. A plurality of third conductive pads 171 may be disposed on the lower surface of the redistribution layer 170. For example, at least a portion of the third conductive pad 171 may not be covered with the lower surface of the redistribution layer 170 so as to be exposed. The fourth conductive pad 172 may be disposed on an upper surface of the redistribution layer 170. A plurality of fourth conductive pads 172 may be disposed on the upper surface of the redistribution layer 170. Although the fourth conductive pad 172 is illustrated as protruding from the upper surface of the redistribution layer 170 in FIG. 1, the present disclosure is not limited thereto.

For example, the third conductive pad 171 may be directly electrically connected to the first semiconductor chip 110. That is, the first semiconductor chip 110 may be directly electrically connected to the redistribution layer 170 via the third conductive pad 171.

Each of the third conductive pad 171 and the fourth conductive pad 172 may include a conductive material. Each of the third conductive pad 171 and the fourth conductive pad 172 may include, for example, at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), or zirconium (Zr). However, the present disclosure is not limited thereto.

The capacitor 130 is disposed in the dummy semiconductor chip 120. For example, the capacitor 130 may be disposed in the base material layer 122. For example, an upper surface of the capacitor 130 may be coplanar with an upper surface of the base material layer 122. However, the present disclosure is not limited thereto. The capacitor 130 may be embodied as a silicon capacitor, a multilayer ceramic capacitor (MLCC), or a low inductance ceramic capacitor (LICC). However, the present disclosure is not limited thereto.

The capacitor insulating layer 135 is disposed in the dummy semiconductor chip 120. For example, the capacitor insulating layer 135 may be disposed in the base material layer 122. The capacitor insulating layer 135 may be disposed along a boundary between the capacitor 130 and the base material layer 122. The capacitor insulating layer 135 may electrically insulate between the capacitor 130 and the base material layer 122 from each other. The capacitor insulating layer 135 may include an insulating material.

The capacitor via 132 is disposed in the dummy semiconductor chip 120. The capacitor via 132 may extend through the second insulating layer 123 in the vertical direction DR2. The capacitor via 132 may electrically connect the capacitor 130 and the third conductive pad 171 to each other. That is, the capacitor 130 may be electrically connected to the redistribution layer 170 via the third conductive pad 171. The capacitor via 132 may include a conductive material.

The first through-via 150 is disposed between the upper surface 100b of the structure 100 and the lower surface of redistribution layer 170. A plurality of first through-vias 150 may be arranged. The first through-via 150 may extend through the first molding layer 140 in the vertical direction DR2. That is, a sidewall of the first through-via 150 may be surrounded with the first molding layer 140. The first through-via 150 may extend from the upper surface 100b of the structure 100 to the lower surface of the redistribution layer 170 in the vertical direction DR2. The first through-via 150 may be spaced apart from each of the first semiconductor chip 110 and the dummy semiconductor chip 120 in the horizontal direction DR1.

The first through-via 150 may be connected to each of the second conductive pad 102 and the third conductive pad 171. That is, the redistribution layer 170 may be electrically connected to the structure 100 via the first through-via 150. The first through-via 150 may include a conductive material. For example, the first through-via 150 may include a metal material such as copper (Cu), aluminum (Al), silver (Ag), tin (Sn), gold (Au), nickel (Ni), lead (Pb), titanium (Ti), or an alloy thereof. However, the present disclosure is not limited thereto.

The second through-via 160 is disposed in the dummy semiconductor chip 120. A plurality of second through-vias 160 may be arranged. The second through-via 160 may be spaced apart from the capacitor 130 in the horizontal direction DR1. The second through-via 160 may extend through the dummy semiconductor chip 120 in the vertical direction DR2. For example, the second through-via 160 may extend through each of the first insulating layer 121, the base material layer 122, and the second insulating layer 123 in the vertical direction DR2.

For example, the second through-via 160 may extend from the lower surface 120a of the dummy semiconductor chip 120 to the upper surface 120b of the dummy semiconductor chip 120 in the vertical direction DR2. That is, the second through-via 160 may extend from the lower surface of the first insulating layer 121 to the upper surface of the second insulating layer 123 in the vertical direction DR2. For example, and a lower surface of the second through-via 160 may be coplanar with the lower surface 120a of the dummy semiconductor chip 120. Moreover, the upper surface of the second through-via 160 may be coplanar with each of the upper surface 120b of the dummy semiconductor chip 120 and the upper surface of the first molding layer 140.

The second through-via 160 may be connected to each of the second conductive pad 102 and the third conductive pad 171. That is, the redistribution layer 170 may be electrically connected to the structure 100 via the second through-via 160. The second through-via 160 may include a conductive material. For example, the second through-via 160 may include a metal material such as copper (Cu), aluminum (Al), silver (Ag), tin (Sn), gold (Au), nickel (Ni), lead (Pb), titanium (Ti), or an alloy thereof. However, the present disclosure is not limited thereto. Although not as shown in FIG. 1, a through-via insulating layer may be disposed along a sidewall of the second through-via 160. The through-via insulating layer may include an insulating material. The through-via insulating layer may electrically insulate the second through-via 160 and the base material layer 122 from each other.

The second semiconductor chip 180 is disposed on the upper surface of the redistribution layer 170. For example, the second semiconductor chip 180 may be a logic semiconductor chip. For example, the second semiconductor chip 180 may be an application processor (AP) such as CPU (Central Processing Unit), GPU (Graphic Processing Unit), FPGA (Field-Programmable Gate Array), a digital signal processor, a cryptographic processor, a microprocessor, a microcontroller, or ASIC (Application-Specific IC).

For example, the second semiconductor chip 180 may be a memory semiconductor chip. For example, the second semiconductor chip 180 may be a volatile memory such as DRAM (dynamic random access memory) or SRAM (static random access memory), or may be a non-volatile memory such as a flash memory, PRAM (Phase-change Random Access Memory), MRAM (Magnetoresistive Random Access Memory), FeRAM (Ferroelectric Random Access Memory) or RRAM (Resistive Random Access Memory). For example, the second semiconductor chip 180 may be embodied as an HBM semiconductor chip including a plurality of memory semiconductor chips.

The fifth conductive pad 181 is disposed on a lower surface of the second semiconductor chip 180. The fifth conductive pad 181 may protrude from the lower surface of the second semiconductor chip 180. However, the present disclosure is not limited thereto. The fifth conductive pad 181 may include, for example, at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), or zirconium (Zr). However, the present disclosure is not limited thereto.

The third connection terminal 185 is disposed between the fourth conductive pad 172 and the fifth conductive pad 181. The second semiconductor chip 180 may be connected to the fourth conductive pad 172 via the third connection terminal 185. The third connection terminal 185 may include, for example, at least one of tin (Sn), indium (In), lead (Pb), zinc (Zn), nickel (Ni), gold (Au), silver (Ag), copper (Cu), antimony (Sb), bismuth (Bi), or combinations thereof. However, the present disclosure is not limited thereto. The second semiconductor chip 180 may be directly electrically connected to the redistribution layer 170 via the fifth conductive pad 181, the third connection terminal 185, and the fourth conductive pad 172.

In the semiconductor package, the dummy semiconductor chip 120 including the base material layer 122 including silicon (Si) may be disposed between the structure 100 and the redistribution layer 170. Further, the second through-via 160 may be disposed in the dummy semiconductor chip 120. Thus, in a process of manufacturing the semiconductor package, the base material layer 122 can prevent warpage of the second through-via 160 disposed in the dummy semiconductor chip 120 from occurring, and thus can prevent the second through-via 160 from deteriorating.

Moreover, in the semiconductor package, the capacitor 130 electrically connected to the redistribution layer 170 may be disposed in the dummy semiconductor chip 120. Thus, in the process of manufacturing the semiconductor package, the dummy semiconductor chip 120 may prevent the damage from being applied to the capacitor 130. Thus, electrical reliability of the capacitor 130 may be improved.

Hereinafter, referring to FIG. 1 to FIG. 7, a method for manufacturing a semiconductor package is described.

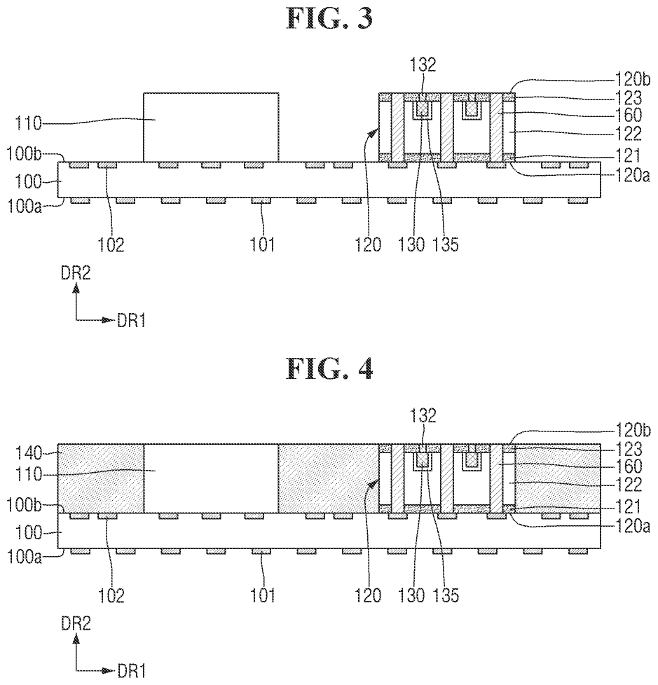

FIG. 3 to FIG. 7 are diagrams of intermediate structures corresponding to intermediate steps to illustrate an example of a method for manufacturing the semiconductor package as shown in FIG. 1.

Referring to FIG. 3, the structure 100 is provided. The first conductive pad 101 is formed on the lower surface 100a of the structure 100, and the second conductive pad 102 is formed on the upper surface 100b of the structure 100. Subsequently, the first semiconductor chip 110 may be mounted on the upper surface 100b of the structure 100. The first semiconductor chip 110 may be connected to the second conductive pad 102. Moreover, the dummy semiconductor chip 120 may be mounted on the upper surface 100b of the structure 100.

The dummy semiconductor chip 120 includes the first insulating layer 121, the base material layer 122 disposed on the first insulating layer 121, and the second insulating layer 123 disposed on the base material layer 122. The capacitor 130, the capacitor via 132, the capacitor insulating layer 135, and the second through-via 160 are disposed in the dummy semiconductor chip 120. The second through-via 160 extends through the dummy semiconductor chip 120 in the vertical direction DR2. The second through-via 160 is connected to the second conductive pad 102.

Referring to FIG. 4, the first molding layer 140 is formed on the upper surface 100b of the structure 100 so as to surround a sidewall of the first semiconductor chip 110 and a sidewall of the dummy semiconductor chip 120. For example, in a planarization process, the upper surface of the first semiconductor chip 110, the upper surface of the dummy semiconductor chip 120, and the upper surface of the first molding layer 140 may be brought into being coplanar with each other. That is, each of the upper surface of the first semiconductor chip 110, the upper surface of the dummy semiconductor chip 120, and the upper surface of the second through-via 160 may not be covered with the upper surface of the first molding layer 140 so as to be exposed.

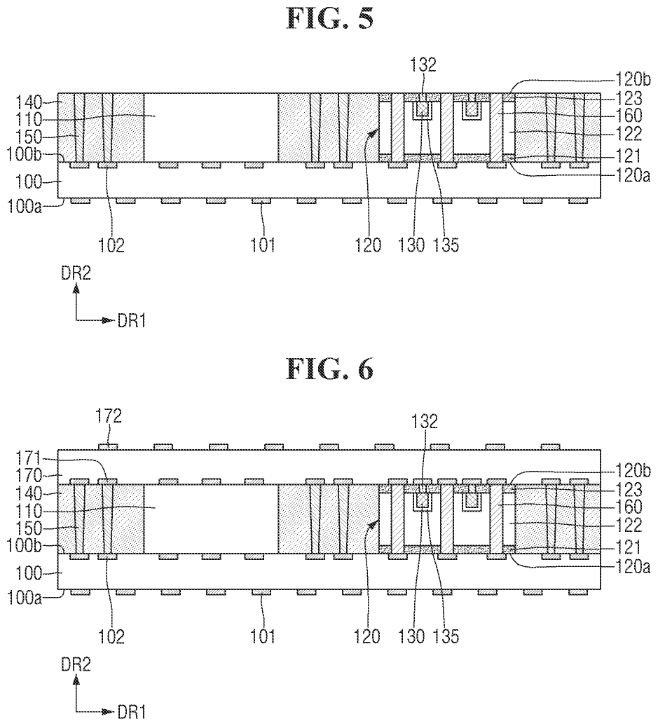

Referring to FIG. 5, the first through-via 150 is formed in the first molding layer 140. The first through-via 150 may extend through the first molding layer 140 in the vertical direction DR2 so as to be connected to the second conductive pad 102. The first through-via 150 may be spaced apart from each of the first semiconductor chip 110 and the dummy semiconductor chip 120 in the horizontal direction DR1. For example, the upper surface of the first through-via 150 may not be covered with the upper surface of the first molding layer 140 so as to be exposed.

Referring to FIG. 6, the redistribution layer 170 is formed on each of the upper surface of the first semiconductor chip 110, the upper surface of the dummy semiconductor chip 120, the upper surface of the first molding layer 140, the upper surface of the first through-via 150, and the upper surface of the second through-via 160. For example, each of the first through-via 150, the second through-via 160, the capacitor via 132, and the first semiconductor chip 110 may be connected to the third conductive pad 171 formed on the lower surface of the redistribution layer 170.

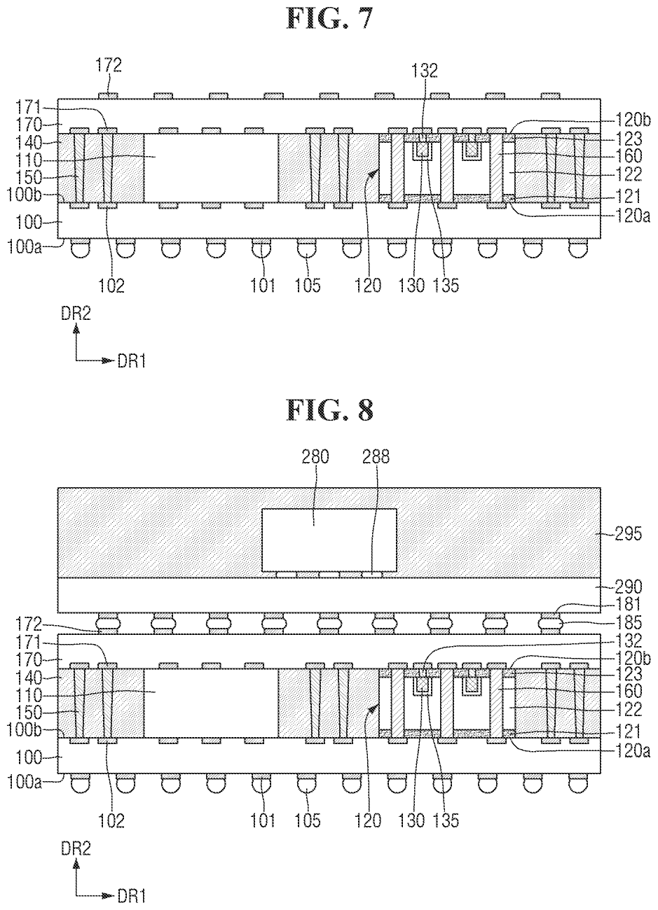

Referring to FIG. 7, the first connection terminal 105 is formed on the first conductive pad 101 disposed on the lower surface 100a of the structure 100.

Referring to FIG. 1, the second semiconductor chip 180 is mounted on the upper surface of the redistribution layer 170. The second semiconductor chip 180 is connected to the fourth conductive pad 172 formed on the upper surface of the redistribution layer 170 via the third connection terminal 185. In this manufacturing process, the semiconductor package as shown in FIG. 1 is manufactured.

Hereinafter, a semiconductor package is described with reference to FIG. 8. Differences thereof from the semiconductor package as shown in FIG. 1 and FIG. 2 will be mainly described. FIG. 8 is a diagram for illustrating an example of a semiconductor package.

Referring to FIG. 8, in the semiconductor package, an upper semiconductor package is disposed on the upper surface of the redistribution layer 170. For example, the upper semiconductor package includes an upper package substrate 290, a second semiconductor chip 280, a fourth connection terminal 288, and a second molding layer 295.

The upper package substrate 290 may be, for example, a printed circuit board (PCB) or a ceramic substrate. However, the present disclosure is not limited thereto. The fifth conductive pad 181 may be disposed on a lower surface of the upper package substrate 290. The upper package substrate 290 may be disposed on the upper surface of the redistribution layer 170 while the third connection terminal 185 may be disposed therebetween. The second semiconductor chip 280 may be disposed on an upper surface of the upper package substrate 290. The second semiconductor chip 280 may be connected to the upper surface of the upper package substrate 290 via the fourth connection terminal 288. The second semiconductor chip 280 may be embodied as an HBM semiconductor chip including a logic semiconductor chip, a memory semiconductor chip, or a plurality of memory semiconductor chips. The fourth connection terminal 288 may include, for example, at least one of tin (Sn), indium (In), lead (Pb), zinc (Zn), nickel (Ni), gold (Au), silver (Ag), copper (Cu), antimony (Sb), bismuth (Bi), or combinations thereof. However, the present disclosure is not limited thereto.

The second molding layer 295 may be disposed on the upper surface of the upper package substrate 290 so as to cover the second semiconductor chip 280. For example, the second molding layer 295 may include, as a base material, PIE (Photo Imagable Encapsulant), epoxy molding compound (EMC), or two or more types of silicon hybrid materials in a form of a film.

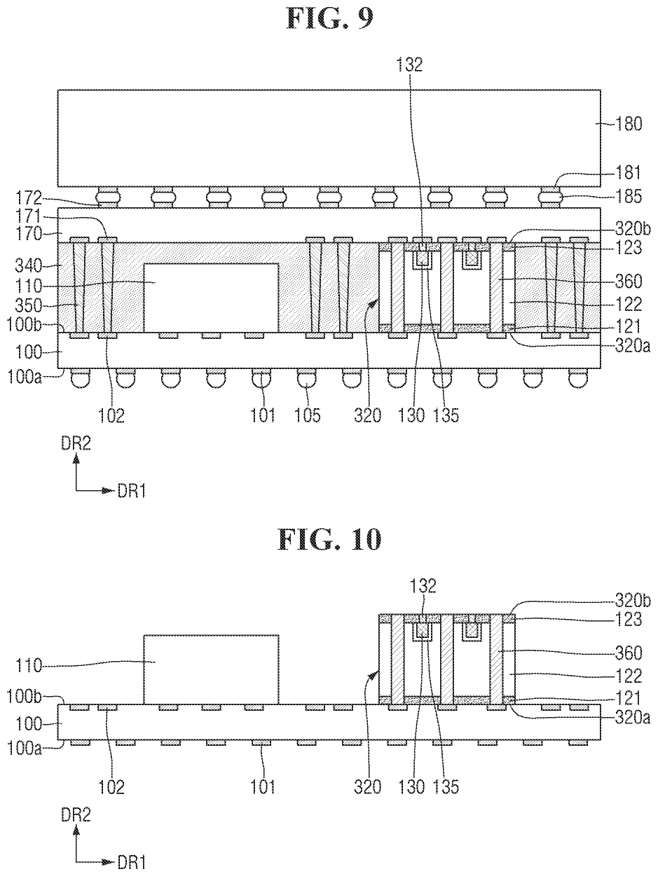

Hereinafter, a semiconductor package will be described with reference to FIG. 9. Differences thereof from the semiconductor package as shown in FIG. 1 and FIG. 2 will be mainly described.

FIG. 9 is a diagram for illustrating another example of a semiconductor package.

Referring to FIG. 9, in the semiconductor package, a vertical level of an upper surface 320b of a dummy semiconductor chip 320 is higher than a vertical level of an upper surface of the first semiconductor chip 110.

For example, an upper surface of a first molding layer 340 may be higher than a vertical level of an upper surface of the first semiconductor chip 110. For example, the upper surface of the first molding layer 340 may be coplanar with an upper surface 320b of the dummy semiconductor chip 320. The redistribution layer 170 may be spaced apart from the upper surface of the first semiconductor chip 110 in the vertical direction DR2. The first molding layer 340 may cover the upper surface of the first semiconductor chip 110. That is, at least a portion of the first molding layer 340 may be disposed between the upper surface of the first semiconductor chip 110 and the lower surface of the redistribution layer 170.

A first through-via 350 may extend through the first molding layer 340 in the vertical direction DR2. The first through-via 350 may extend from the upper surface 100b of the structure 100 to the lower surface of the redistribution layer 170 in the vertical direction DR2. A second through-via 360 may extend through the dummy semiconductor chip 320 in the vertical direction DR2. The second through-via 360 may extend from the lower surface 320a of the dummy semiconductor chip 320 to the upper surface 320b of the dummy semiconductor chip 320 in the vertical direction DR2.

Hereinafter, a method for manufacturing a semiconductor package is described with reference to FIG. 9 to FIG. 14.

FIG. 10 to FIG. 14 are diagrams of intermediate structures corresponding to intermediate steps to illustrate an example of a method for manufacturing the semiconductor package as shown in FIG. 9.

Referring to FIG. 10, the structure 100 is provided. The first conductive pad 101 is formed on the lower surface 100a of the structure 100, and the second conductive pad 102 is formed on the upper surface 100b of the structure 100. Subsequently, the first semiconductor chip 110 may be mounted on the upper surface 100b of the structure 100. The first semiconductor chip 110 may be connected to the second conductive pad 102. Moreover, the dummy semiconductor chip 320 may be mounted on the upper surface 100b of the structure 100. The upper surface 320b of the dummy semiconductor chip 320 may be located at a higher level than that of the upper surface of the first semiconductor chip 110.

The dummy semiconductor chip 320 may include the first insulating layer 121, the base material layer 122 disposed on the first insulating layer 121, and the second insulating layer 123 disposed on the base material layer 122. The capacitor 130, the capacitor via 132, the capacitor insulating layer 135, and the second through-via 360 may be disposed in the dummy semiconductor chip 320. The second through-via 360 may extend through the dummy semiconductor chip 320 in the vertical direction DR2. The second through-via 360 may be connected to the second conductive pad 102.

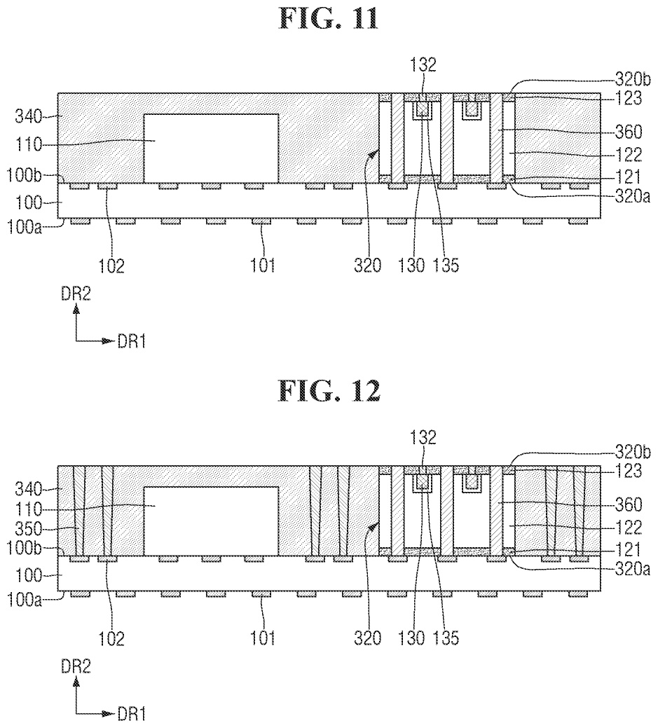

Referring to FIG. 11, the first molding layer 340 is formed on the upper surface 100b of the structure 100 so as to surround the sidewall of the first semiconductor chip 110 and the sidewall of the dummy semiconductor chip 320. For example, in a planarization process, the upper surface of the dummy semiconductor chip 320 and the upper surface of the first molding layer 340 may be brought into being coplanar with each other. That is, each of the upper surface of the dummy semiconductor chip 320 and the upper surface of the second through-via 360 may not be covered with the upper surface of the first molding layer 340 so as to be exposed. The first molding layer 340 may cover the upper surface of the first semiconductor chip 110.

Referring to FIG. 12, the first through-via 350 is formed in the first molding layer 340. The first through-via 350 may extend through the first molding layer 340 in the vertical direction DR2 so as to be connected to the second conductive pad 102. The first through-via 350 may be spaced apart from each of the first semiconductor chip 110 and the dummy semiconductor chip 320 in the horizontal direction DR1. For example, the upper surface of the first through-via 350 may not be covered with the upper surface of the first molding layer 340 so as to be exposed.

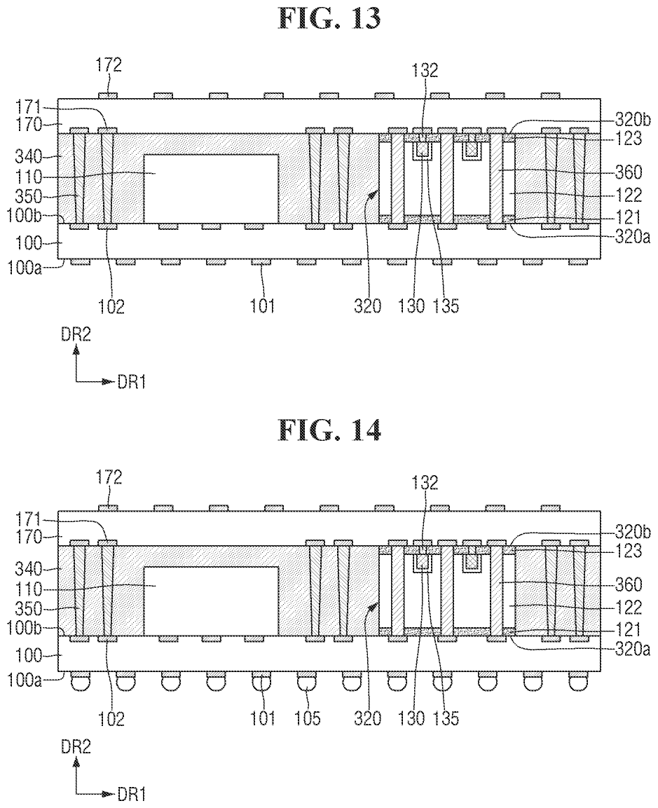

Referring to FIG. 13, the redistribution layer 170 is formed on each of the upper surface of the dummy semiconductor chip 320, the upper surface of the first molding layer 340, the upper surface of the first through-via 350, and the upper surface of the second through-via 360. The redistribution layer 170 may be spaced apart from the upper surface of the first semiconductor chip 110 in the vertical direction DR2. For example, each of the first through-via 350, the second through-via 360, the capacitor via 132, and the first semiconductor chip 110 may be connected to the third conductive pad 171 formed on the lower surface of the redistribution layer 170.

Referring to FIG. 14, the first connection terminal 105 is formed on the first conductive pad 101 disposed on the lower surface 100a of the structure 100.

Referring to FIG. 9, the second semiconductor chip 180 is mounted on the upper surface of the redistribution layer 170. The second semiconductor chip 180 is connected to the fourth conductive pad 172 formed on the upper surface of the redistribution layer 170 via the third connection terminal 185. In this manufacturing process, the semiconductor package as shown in FIG. 9 is manufactured.

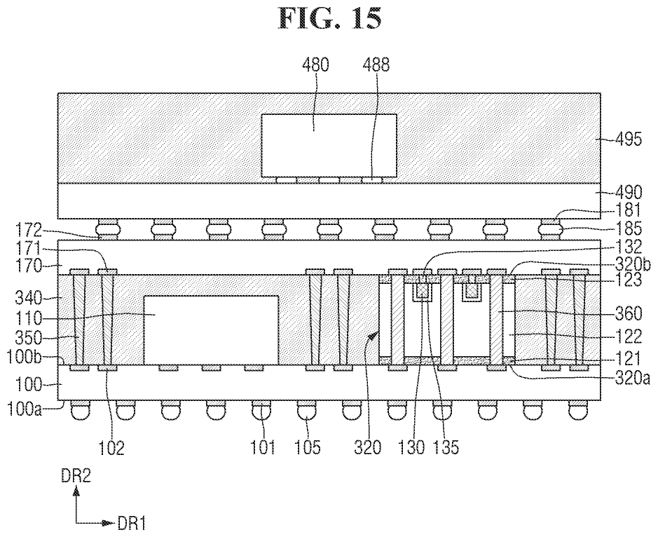

Hereinafter, a semiconductor package is described with reference to FIG. 15. Differences thereof from the semiconductor package as shown in FIG. 9 will be mainly described.

FIG. 15 is a diagram for illustrating another example of a semiconductor package.

Referring to FIG. 15, in the semiconductor package, an upper semiconductor package is disposed on the upper surface of the redistribution layer 170. For example, the upper semiconductor package may include an upper package substrate 490, a second semiconductor chip 480, a fourth connection terminal 488, and a second molding layer 495.

The upper package substrate 490 may be, for example, a printed circuit board (PCB) or a ceramic substrate. However, the present disclosure is not limited thereto.

The fifth conductive pad 181 is disposed on a lower surface of the upper package substrate 490. The upper package substrate 490 may be disposed on the upper surface of the redistribution layer 170 while the third connection terminal 185 may be disposed therebetween.

The second semiconductor chip 480 is disposed on an upper surface of the upper package substrate 490. The second semiconductor chip 480 may be connected to the upper surface of the upper package substrate 490 via the fourth connection terminal 488. The second semiconductor chip 480 may be embodied as an HBM semiconductor chip including a logic semiconductor chip, a memory semiconductor chip, or a plurality of memory semiconductor chips. The fourth connection terminal 488 may include, for example, at least one of tin (Sn), indium (In), lead (Pb), zinc (Zn), nickel (Ni), gold (Au), silver (Ag), copper (Cu), antimony (Sb), bismuth (Bi), or combinations thereof. However, the present disclosure is not limited thereto.

The second molding layer 495 is formed on the upper surface of the upper package substrate 490 so as to cover the second semiconductor chip 480. For example, the second molding layer 495 may include, as a base material, PIE (Photo Imagable Encapsulant), epoxy molding compound (EMC), or two or more types of silicon hybrid materials in a form of a film.

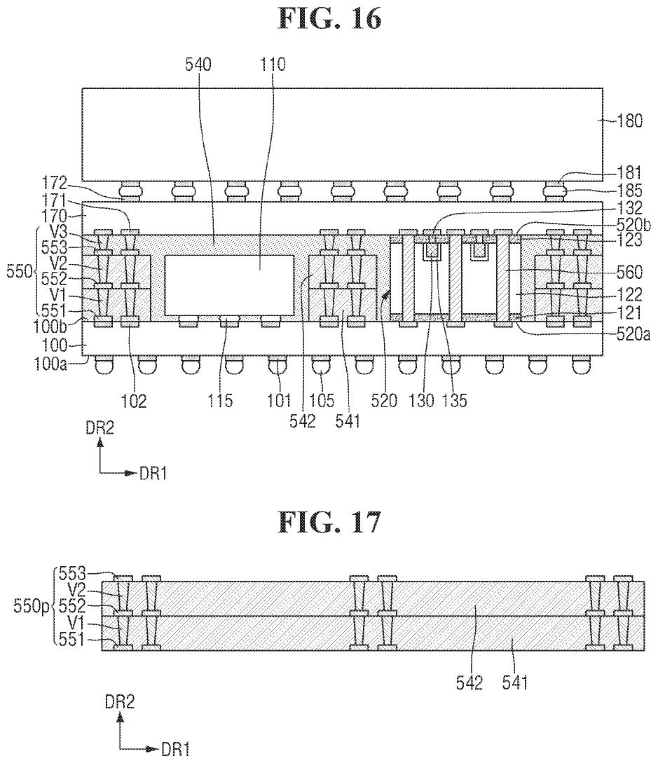

Hereinafter, a semiconductor package is described with reference to FIG. 16. Differences thereof from the semiconductor package as shown in FIG. 1 and FIG. 2 will be mainly described. FIG. 16 is a diagram for illustrating another example of a semiconductor package.

Referring to FIG. 16, the semiconductor package has a fan-out panel level package structure. For example, the semiconductor package includes a second connection terminal 115, a first stack insulating layer 541, a second stack insulating layer 542, a first molding layer 540, a dummy semiconductor chip 520, a first through-via 550, and a second through-via 560.

For example, the first semiconductor chip 110 is connected to the second conductive pad 102 via the second connection terminal 115. The second connection terminal 115 may include, for example, at least one of tin (Sn), indium (In), lead (Pb), zinc (Zn), nickel (Ni), gold (Au), silver (Ag), copper (Cu), antimony (Sb), bismuth (Bi), or combinations thereof. However, the present disclosure is not limited thereto. The first semiconductor chip 110 may be directly electrically connected to the structure 100 via the second connection terminal 115 and the second conductive pad 102.

For example, the first stack insulating layer 541 is disposed on the upper surface 100b of the structure 100. For example, the structure 100 acts as a redistribution layer. For example, while being disposed on a plane parallel to the upper surface 100b of the structure 100, the first stack insulating layer 541 surrounds each of the sidewall of the first semiconductor chip 110 and the sidewall of the dummy semiconductor chip 520. The first stack insulating layer 541 may be spaced apart from each of the sidewall of the first semiconductor chip 110 and the sidewall of the dummy semiconductor chip 520 in the horizontal direction DR1.

The second stack insulating layer 542 is disposed on an upper surface of the first stack insulating layer 541. The second stack insulating layer 542 contacts the upper surface of the first stack insulating layer 541. For example, a sidewall of the second stack insulating layer 542 is aligned with a sidewall of the first stack insulating layer 541 in the vertical direction DR2. For example, while being disposed on the plane parallel to the upper surface 100b of the structure 100, the second stack insulating layer 542 surrounds each of the sidewall of the first semiconductor chip 110 and the sidewall of the dummy semiconductor chip 520. The second stack insulating layer 542 may be spaced apart from each of the sidewall of the first semiconductor chip 110 and the sidewall of the dummy semiconductor chip 520 in the horizontal direction DR1.

Each of the first stack insulating layer 541 and the second stack insulating layer 542 includes at least one of, for example, epoxy resin, polyimide, PPG (prepreg), ABF (Ajinomoto Build-up Film), FR-4, or BT (Bismaleimide Triazine). However, the present disclosure is not limited thereto.

The first molding layer 540 covers a sidewall and an upper surface of each of the first stack insulating layer 541, the second stack insulating layer 542, and the first semiconductor chip 110. The first molding layer 540 may surround a sidewall of the dummy semiconductor chip 520. The first molding layer 540 may be disposed between each of the first and second stack insulating layers 541 and 542 and the first semiconductor chip 110. Moreover, the first molding layer 540 may be disposed between each of the first and second stack insulating layers 541 and 542 and the dummy semiconductor chip 520. For example, an upper surface of the first molding layer 540 may be coplanar with an upper surface 520b of the dummy semiconductor chip 520.

The first through-via 550 extends through the first stack insulating layer 541, the second stack insulating layer 542, and the first molding layer 540 in the vertical direction DR2. For example, the first through-via 550 may include a first via pad 551, a first via V1, a second via pad 552, a second via V2, a third via pad 553, and a third via V3. The first via pad 551 may be disposed in the first stack insulating layer 541. For example, a lower surface of the first via pad 551 may not be covered with a lower surface of the first stack insulating layer 541 so as to be exposed. The first via pad 551 may be connected to the second conductive pad 102. The first via V1 may extend through the first stack insulating layer 541 in the vertical direction DR2 so as to be connected to the first via pad 551.

The second via pad 552 is disposed in the second stack insulating layer 542. For example, a lower surface of the second via pad 552 may be connected to the first via V1. The second via V2 may extend through the second stack insulating layer 542 in the vertical direction DR2 so as to be connected to the second via pad 552. The third via pad 553 may be disposed in the first molding layer 540. The third via pad 553 may be disposed on the upper surface of the second stack insulating layer 542. For example, the lower surface of the third via pad 553 may be connected to the second via V2. The third via V3 may extend through the first molding layer 540 in the vertical direction DR2 so as to be connected to the third via pad 553. The third via V3 may be connected to the third conductive pad 171. Each of the first to third via pads 551, 552, and 553, and each of the first to third vias V1, V2, and V3 may include a conductive material.

The second through-via 560 extends through the dummy semiconductor chip 520 in the vertical direction DR2. The second through-via 560 may extend from the lower surface 520a of the dummy semiconductor chip 520 to the upper surface 520b of the dummy semiconductor chip 520 in the vertical direction DR2.

Hereinafter, a method for manufacturing a semiconductor package will be described with reference to FIG. 16 to FIG. 24.

FIG. 17 to FIG. 24 are diagrams of intermediate structures corresponding to intermediate steps for illustrating an example of a method for manufacturing the semiconductor package as shown in FIG. 16.

Referring to FIG. 17, the first stack insulating layer 541 and the second stack insulating layer 542 in which a plurality of pre-first through-vias 550p spaced apart from each other in the horizontal direction DR1 are formed. The second stack insulating layer 542 may be formed on the upper surface of the first stack insulating layer 541. The pre-first through-via 550p may include the first via pad 551, the first via V1, the second via pad 552, the second via V2, and the third via pad 553. The pre-first through-via 550p may extend through the first stack insulating layer 541 and the second stack insulating layer 542 in the vertical direction DR2.

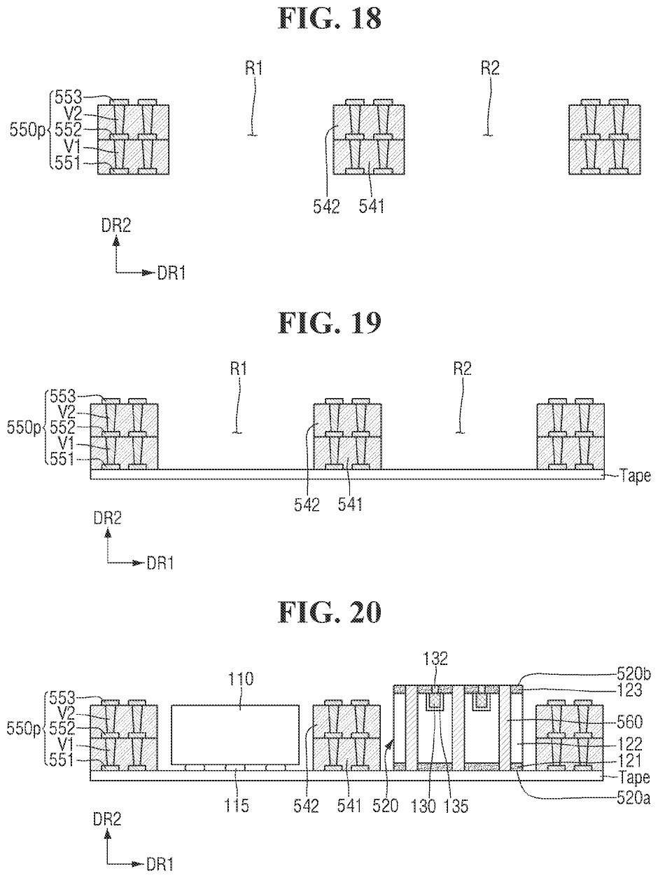

Referring to FIG. 18, each of a first recess R1 and a second recess R2 is formed between adjacent ones of the plurality of pre-first through-vias 550p. Each of the first recess R1 and the second recess R2 may be formed so as to extend through the first stack insulating layer 541 and the second stack insulating layer 542. The second recess R2 may be spaced apart from the first recess R1 in the horizontal direction DR1. For example, the first stack insulating layer 541, the second stack insulating layer 542, and the pre-first through-via 550p may be positioned between the second recess R2 and the first recess R1.

Referring to FIG. 19, a tape is attached to a lower surface of the first stack insulating layer 541. The tape may constitute a bottom surface of each of the first recess R1 and the second recess R2.

Referring to FIG. 20, the first semiconductor chip 110 is mounted in the first recess (R1 of FIG. 19). The first semiconductor chip 110 may be attached to the tape via the second connection terminal 115. Moreover, the dummy semiconductor chip 520 may be mounted in the second recess (R2 of FIG. 19). The dummy semiconductor chip 520 may include the first insulating layer 121, the base material layer 122 disposed on the first insulating layer 121, and the second insulating layer 123 disposed on the base material layer 122. The capacitor 130, the capacitor via 132, the capacitor insulating layer 135, and the second through-via 560 may be disposed in the dummy semiconductor chip 520. The second through-via 560 may extend through the dummy semiconductor chip 520 in the vertical direction DR2.

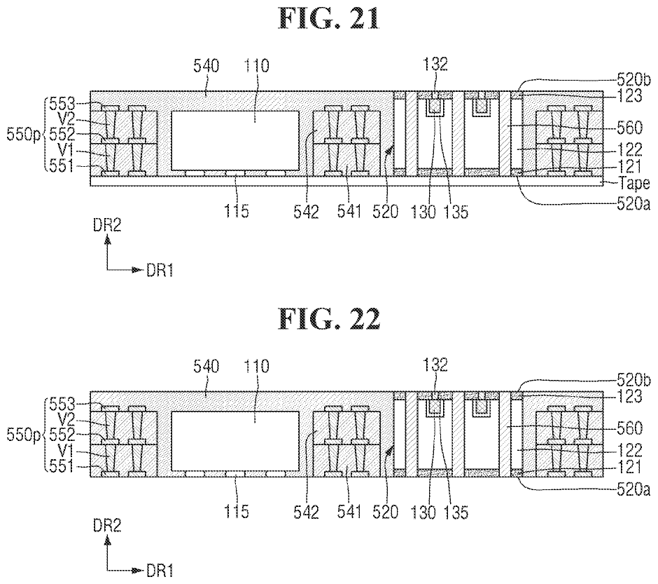

Referring to FIG. 21, the first molding layer 540 is formed on the upper surface of the tape so as to surround the sidewall of the first semiconductor chip 110 and the sidewall of the dummy semiconductor chip 520. For example, under a planarization process, the upper surface of the dummy semiconductor chip 520 and the upper surface of the first molding layer 540 may be brought into being coplanar with each other. That is, each of the upper surface of the dummy semiconductor chip 520 and the upper surface of the second through-via 560 may not be covered with the upper surface of the first molding layer 540 so as to be exposed. The first molding layer 540 may cover the upper surface of the first semiconductor chip 110.

Referring to FIG. 22, the tape is removed.

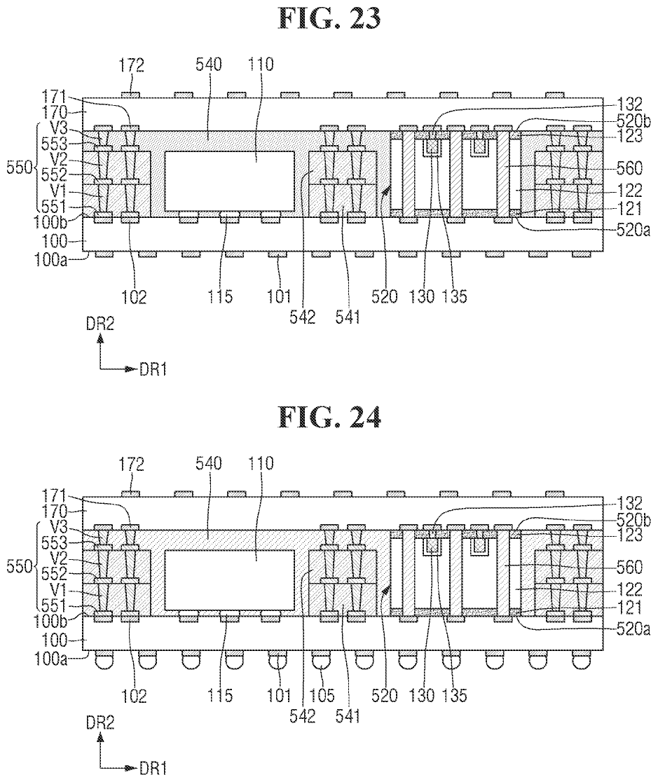

Referring to FIG. 23, the structure 100 is attached to the surface from which the tape has been removed. The third via V3 extending through the first molding layer 540 in the vertical direction DR2 so as to be connected to the third via pad 553 of the pre-first through-via (550p of FIG. 22) may be formed. Accordingly, the first through-via 550 including the first via pad 551, the first via V1, the second via pad 552, the second via V2, the third via pad 553, and the third via V3 may be defined. Subsequently, the redistribution layer 170 may be formed on the upper surface of the first molding layer 540 and the upper surface 520b of the dummy semiconductor chip 520.

Referring to FIG. 24, the first connection terminal 105 is formed on the first conductive pad 101 disposed on the lower surface 100a of the structure 100.

Referring to FIG. 16, the second semiconductor chip 180 is mounted on the upper surface of the redistribution layer 170. The second semiconductor chip 180 may be connected to the fourth conductive pad 172 formed on the upper surface of the redistribution layer 170 via the third connection terminal 185. In this manufacturing process, the semiconductor package as shown in FIG. 16 may be manufactured.

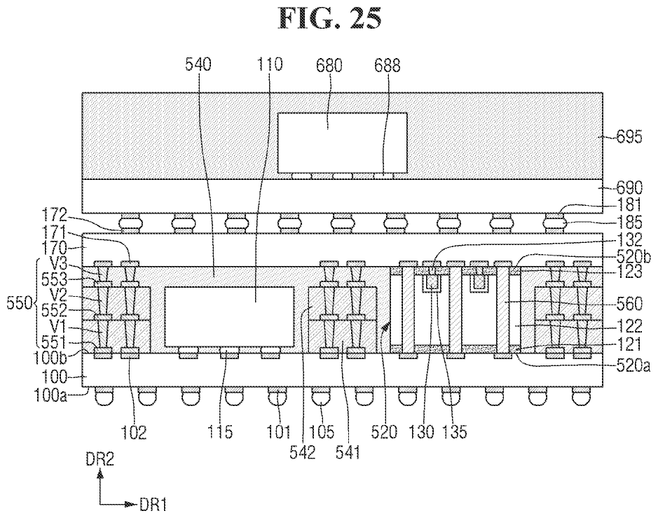

Hereinafter, a semiconductor package is described with reference to FIG. 25. Differences thereof from the semiconductor package as shown in FIG. 16 will be mainly described.

FIG. 25 is a diagram for illustrating another example of a semiconductor package.

Referring to FIG. 25, in the semiconductor package, an upper semiconductor package is disposed on the upper surface of the redistribution layer 170. For example, the upper semiconductor package may include an upper package substrate 690, a second semiconductor chip 680, a fourth connection terminal 688, and a second molding layer 695.

The upper package substrate 690 may be, for example, a printed circuit board (PCB) or a ceramic substrate. However, the present disclosure is not limited thereto.

The fifth conductive pad 181 may be disposed on the lower surface of the upper package substrate 690. The upper package substrate 690 may be disposed on the upper surface of the redistribution layer 170 while the third connection terminal 185 may be disposed therebetween.

The second semiconductor chip 680 may be disposed on the upper surface of the upper package substrate 690. The second semiconductor chip 680 may be connected to the upper surface of the upper package substrate 690 via the fourth connection terminal 688. The second semiconductor chip 680 may be embodied as an HBM semiconductor chip including a logic semiconductor chip, a memory semiconductor chip, or a plurality of memory semiconductor chips. The fourth connection terminal 688 may include, for example, at least one of tin (Sn), indium (In), lead (Pb), zinc (Zn), nickel (Ni), gold (Au), silver (Ag), copper (Cu), antimony (Sb), bismuth (Bi), or combinations thereof. However, the present disclosure is not limited thereto.

The second molding layer 695 may be disposed on the upper surface of the upper package substrate 690 so as to cover the second semiconductor chip 680. For example, the second molding layer 695 may include, as a base material, PIE (Photo Imagable Encapsulant), epoxy molding compound (EMC), or two or more types of silicon hybrid materials in a form of a film.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Although the implementations of the present disclosure have been described with reference to the accompanying drawings, the present disclosure is not limited to the above implementations and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the implementations as described above are not restrictive but illustrative in all respects.

What is claimed is:

1. A semiconductor package comprising:
a structure;
a first semiconductor chip disposed on an upper surface of the structure and electrically connected to the structure directly;
a dummy semiconductor chip disposed on the upper surface of the structure, the dummy semiconductor chip in contact with the upper surface of the structure, the dummy semiconductor chip spaced apart from the first semiconductor chip in a horizontal direction, and the dummy semiconductor chip including silicon;
a molding layer surrounding a sidewall of the first semiconductor chip and a sidewall of the dummy semiconductor chip on the upper surface of the structure;
a redistribution layer disposed on an upper surface of the first semiconductor chip, an upper surface of the dummy semiconductor chip, and an upper surface of the molding layer;
a first through-via extending through the molding layer in a vertical direction, the first through-via electrically connecting the structure and the redistribution layer;
a second through-via extending through the dummy semiconductor chip in the vertical direction, the second through-via electrically connecting the structure and the redistribution layer; and
a capacitor disposed inside the dummy semiconductor chip and electrically connected to the redistribution layer.

2. The semiconductor package of claim 1, wherein the dummy semiconductor chip includes:
a first insulating layer disposed on the upper surface of the structure;
a base material layer disposed on the first insulating layer and including silicon; and
a second insulating layer disposed on the base material layer, and
wherein the second through-via extends through the first insulating layer, the base material layer, and the second insulating layer in the vertical direction.

3. The semiconductor package of claim 2, wherein the capacitor is disposed inside the base material layer.

4. The semiconductor package of claim 3, further comprising a capacitor insulating layer disposed between the capacitor and the base material layer.

5. The semiconductor package of claim 1, wherein the upper surface of the dummy semiconductor chip contacts a lower surface of the redistribution layer.

6. The semiconductor package of claim 1, wherein a lower surface of the second through-via is coplanar with a lower surface of the dummy semiconductor chip, and
wherein an upper surface of the second through-via is coplanar with the upper surface of the dummy semiconductor chip.

7. The semiconductor package of claim 1, further comprising a second semiconductor chip disposed on an upper surface of the redistribution layer and electrically connected to the redistribution layer directly.

8. The semiconductor package of claim 1, further comprising:
an upper package substrate disposed on an upper surface of the redistribution layer; and
a second semiconductor chip disposed on an upper surface of the upper package substrate.

9. The semiconductor package of claim 1, wherein the upper surface of the first semiconductor chip contacts the redistribution layer, and
wherein the first semiconductor chip is directly and electrically connected to the redistribution layer.

10. The semiconductor package of claim 1, wherein the upper surface of the first semiconductor chip, the upper surface of the dummy semiconductor chip, and the upper surface of the molding layer are coplanar.

11. The semiconductor package of claim 1, wherein a vertical level of the upper surface of the dummy semiconductor chip and a vertical level of the upper surface of the molding layer are higher than a vertical level of the upper surface of the first semiconductor chip.

12. The semiconductor package of claim 1, further comprising:
a first stack insulating layer disposed on the upper surface of the structure, the first stack insulating layer spaced apart from the sidewall of the first semiconductor chip and the sidewall of the dummy semiconductor chip in the horizontal direction; and
a second stack insulating layer disposed on the first stack insulating layer, the second stack insulating layer spaced apart from the sidewall of the first semiconductor chip and the sidewall of the dummy semiconductor chip in the horizontal direction,
wherein the molding layer covers the first stack insulating layer, the second stack insulating layer, and the first semiconductor chip, and
wherein the first through-via extends through the first stack insulating layer, the second stack insulating layer, and the molding layer in the vertical direction.

13. The semiconductor package of claim 12, wherein the molding layer is disposed between the first and second stack insulating layers and the first semiconductor chip, and between the first and second stack insulating layers and the dummy semiconductor chip.

14. A semiconductor package comprising:
a structure;
a semiconductor chip disposed on an upper surface of the structure and electrically connected to the structure directly;
a dummy semiconductor chip disposed on the upper surface of the structure, the dummy semiconductor chip in contact with the upper surface of the structure, the dummy semiconductor chip spaced apart from the semiconductor chip in a horizontal direction, the dummy semiconductor chip including a first insulating layer disposed on the upper surface of the structure, a base material layer disposed on the first insulating layer and including silicon, and a second insulating layer disposed on the base material layer;
a molding layer surrounding a sidewall of the semiconductor chip and a sidewall of the dummy semiconductor chip on the upper surface of the structure;
a first through-via extending through the molding layer in a vertical direction, the first through-via electrically connected to the structure;
a second through-via extending through the first insulating layer, the base material layer, and the second insulating layer in the vertical direction, the second through-via electrically connected to the structure; and
a capacitor disposed inside the base material layer,
wherein an upper surface of the molding layer, an upper surface of the second through-via, and an upper surface of the dummy semiconductor chip are coplanar.

15. The semiconductor package of claim 14, further comprising a redistribution layer disposed on an upper surface of the semiconductor chip, the upper surface of the dummy semiconductor chip, and the upper surface of the molding layer, the redistribution layer electrically connected to the first through-via, the second through-via, and the capacitor.

16. The semiconductor package of claim 15, wherein the upper surface of the semiconductor chip contacts the redistribution layer, and the semiconductor chip is directly and electrically connected to the redistribution layer.

17. The semiconductor package of claim 15, wherein at least a portion of the molding layer is disposed between the upper surface of the semiconductor chip and a lower surface of the redistribution layer.

18. The semiconductor package of claim 14, further comprising a capacitor insulating layer disposed between the capacitor and the base material layer.

19. The semiconductor package of claim 14, further comprising:
a first stack insulating layer disposed on the upper surface of the structure, the first stack insulating layer spaced apart from the sidewall of the semiconductor chip and the sidewall of the dummy semiconductor chip in the horizontal direction; and
a second stack insulating layer disposed on the first stack insulating layer, the second stack insulating layer spaced apart from the sidewall of the semiconductor chip and the sidewall of the dummy semiconductor chip in the horizontal direction,
wherein the molding layer covers the first stack insulating layer, the second stack insulating layer, and the semiconductor chip, and
wherein the first through-via extends through the first stack insulating layer, the second stack insulating layer, and the molding layer in the vertical direction.

20. A semiconductor package comprising:
a structure;
a semiconductor chip disposed on an upper surface of the structure and electrically connected to the structure directly;
a dummy semiconductor chip disposed on the upper surface of the structure, the dummy semiconductor chip in contact with the upper surface of the structure, the dummy semiconductor chip spaced apart from the semiconductor chip in a horizontal direction, the dummy semiconductor chip including a first insulating layer disposed on the upper surface of the structure, a base material layer disposed on the first insulating layer and including silicon, and a second insulating layer disposed on the base material layer;
a molding layer surrounding a sidewall of the semiconductor chip and a sidewall of the dummy semiconductor chip on the upper surface of the structure;
a redistribution layer disposed on an upper surface of the semiconductor chip, an upper surface of the dummy semiconductor chip, and an upper surface of the molding layer;
a first through-via extending through the molding layer in a vertical direction, the first through-via electrically connecting the structure and the redistribution layer;
a second through-via extending through the first insulating layer, the base material layer, and the second insulating layer in the vertical direction, the second through-via electrically connecting the structure and the redistribution layer; and
a capacitor disposed inside the base material layer, the capacitor electrically connected to the redistribution layer,
wherein a lower surface of the second through-via is coplanar with a lower surface of the dummy semiconductor chip,
wherein the upper surface of the molding layer, the upper surface of the second through-via, and the upper surface of the dummy semiconductor chip are coplanar, and
wherein the upper surface of the semiconductor chip contacts the redistribution layer, and the semiconductor chip is directly and electrically connected to the redistribution layer.
